(19) United States
(12) Patent Application Publication
(10) Pub. No.: US 2015/0255501 A1
(43) Pub. Date: Sep. 10, 2015

(54) SOLID STATE IMAGING DEVICE AND METHOD OF FABRICATING THE SAME

(71) Applicant: KABUSHIKI KAISHA TOSHIBA, Tokyo (JP)

(72) Inventor: Masahiko MURANO, Oita (JP)

(21) Appl. No.: 14/518,495

(22) Filed: Oct. 20, 2014

(30) Foreign Application Priority Data
Mar. 5, 2014 (JP) 2014-042884

(51) Int. Cl. H01L 27/146; H01L 31/028; H01L 31/18

(52) U.S. Cl. CPC H01L 27/14645; H01L 27/14612; H01L 27/14621; H01L 27/14627; H01L 27/1463; H01L 27/14636; H01L 27/14689; H01L 31/1812; H01L 31/028; H01L 27/14685

(57) ABSTRACT

According to one embodiment, a first semiconductor layer is of a first conductivity type. A second semiconductor layer is of the first conductivity type, is provided on the first semiconductor layer and is larger in absorbance coefficient to light rays in a long wavelength region than the first semiconductor layer. A third semiconductor layer is of the first conductivity type, is provided on the second semiconductor layer. A first semiconductor regions are of a second conductivity type, and are located to extend over the respective insides of the first, second and third semiconductor layers, and arranged apart from each other in a first direction parallel to the upper surface of the first semiconductor layer. A element isolation portion is arranged between adjacent ones of the first semiconductor regions.

### CROSS REFERENCE TO RELATED APPLICATION

This application is based upon and claims the benefit of priority from the prior Japanese Patent Application No. 2014-042884, filed on Mar. 5, 2014, the entire contents of which are incorporated herein by reference.

### FIELD

Embodiments described herein relate to a solid state imaging device, and a method of fabricating the device.

### BACKGROUND

In optical instruments such as a camera, a solid state imaging device is used. Examples of the solid state imaging device include a CCD (charge coupled device) image sensor, and a CMOS (complementary metal oxide semiconductor) image sensor, and the like. In the CMOS image sensor, a plurality of pixels is arranged in a matrix form. Each of the pixels has a photodiode, and a transistor for readout, or the like. Color filters, as well as microlenses, are provided over the pixels, respectively, to be provided over the respective upper surfaces of the pixels. Light is transmitted through the color filters, which are each in one color of the three primary colors, so that rays of the light which are in respective wavelength regions of the colors are each absorbed in the corresponding photodiodes. Each of the photodiodes has a function of converting the absorbed light ray in one of the individual wavelength regions to a signal charge. When the photodiodes are made of silicon, the photodiodes cannot sufficiently absorb any light ray in the red wavelength bandwidth. It is therefore difficult to improve the sensor in image quality.

### BRIEF DESCRIPTION OF THE DRAWINGS

FIG. 1 is a sectional view of a configuration of a solid state imaging device according to a first embodiment;

FIGS. 2A and 2B are each a graph showing the composition ratio of Ge (germanium) in SiGe (silicon germanium) of a long wavelength absorption layer relative to the depth of the layer;

FIG. 3 is a plan view of the solid state imaging device along line A-A in FIG. 1;

FIG. 4 is a characteristic diagram illustrating the absorption coefficient of each material relative to the wavelength (energy) of light;

FIG. 5 is a sectional view illustrating a step in a process of fabricating the solid state imaging device according to the first embodiment;

FIG. 6 is a sectional view illustrating a step in the process of fabricating the solid state imaging device according to the first embodiment;

FIG. 7 is a sectional view illustrating a step in the process of fabricating the solid state imaging device according to the first embodiment;

FIG. 8 is a sectional view illustrating a step in the process of fabricating the solid state imaging device according to the first embodiment;

FIG. 9 is a sectional view illustrating a step in the process of fabricating the solid state imaging device according to the first embodiment;

FIG. 10 is a sectional view illustrating a step in the process of fabricating the solid state imaging device according to the first embodiment;

FIG. 11 is a sectional view of a configuration of a solid state imaging device according to a second embodiment; and.

FIG. 12 is a chart showing a profile of an impurity in a first semiconductor region relative to the depth direction of the region.

### DETAILED DESCRIPTION

According to one embodiment, the solid state imaging device includes a first semiconductor layer, a second semiconductor layer, a third semiconductor layer, first semiconductor regions, and an element isolation portion. The first semiconductor layer is of a first conductivity type. The second semiconductor layer is of the first conductivity type, contacts the first semiconductor layer and is larger in absorbance coefficient to light rays in a long wavelength region than the first semiconductor layer. The third semiconductor layer is of the first conductivity type, contacts the second semiconductor layer and is arranged oppositely to the first semiconductor layer. The first semiconductor regions are of a second conductivity type, and are located to extend over the respective insides of the first, second and third semiconductor layers, and arranged apart from each other in a first direction parallel to the upper surface of the first semiconductor layer. The element isolation portion is arranged between adjacent ones of the first semiconductor regions.

Hereinafter, embodiments will be described with reference to the drawings. In the drawings, the same reference numbers or signs represent members or portions identical or similar to each other.

Semiconductor devices according to the embodiments are each a CMOS image sensor for example. Herein, a backside illumination type CMOS image sensor is demonstrated as an example. In any backside illumination type CMOS image sensor, an interconnection layer is arranged below N-type semiconductor regions.

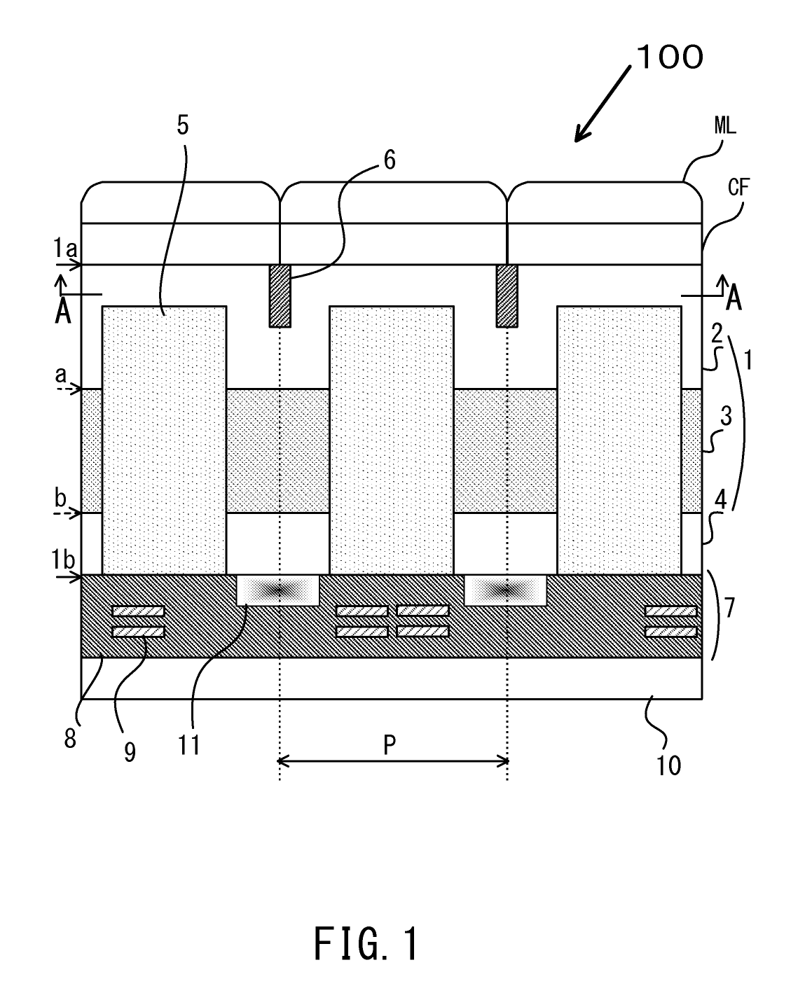

A first embodiment of the invention will be described with reference to FIGS. 1 to 3. FIG. 1 is a sectional view of a configuration of a solid state imaging device according to the first embodiment.

As illustrated in FIG. 1, the solid state imaging device 100 has a semiconductor layer 1, N-type semiconductor regions 5, an interconnection layer 7, color filters CF, and microlens ML.

The semiconductor layer 1 has a first surface 1a, and a second surface 1b opposite to the first surface 1a. The semiconductor layer 1 has a silicon epitaxial layer 2 (first semiconductor layer), a long wavelength absorption layer 3 (second semiconductor layer), and a silicon epitaxial layer 4 (third semiconductor layer). From the first surface 1a toward the second surface 1b, the silicon epitaxial layer 2 (first semiconductor layer), the long wavelength absorption layer 3 (second semiconductor layer), and the silicon epitaxial layer 4 (third semiconductor layer) are successively provided. The silicon epitaxial layer 2 (first semiconductor layer) is a P-type semiconductor layer high in impurity concentration. The long wavelength absorption layer 3 (second semiconductor layer) is a P-type semiconductor layer. The silicon epitaxial layer 4 (third semiconductor layer) is a P-type semiconductor layer lower in impurity concentration than the silicon epitaxial layer 2 (first semiconductor layer).

In the solid state imaging device 100, which is of a backside illumination type, the interconnection layer 7 is laid oppositely to the long wavelength absorption layer 3 to interpose the silicon epitaxial layer 4 between the layers 7 and 3 (details of the situation will be described later). The interconnection layer 7 is provided on the second surface 1b of the semiconductor layer 1. The N-type semiconductor regions 5 (first semiconductor regions) are located inside the semiconductor layer 1 (details of the situation will be described later). Light radiated into the individual layers of the semiconductor layer 1 and the N-type semiconductor regions 5 is subjected to photoelectric conversion to generate a signal charge. The signal charge is passed through pixel transistors 11 in the interconnection layer 7, and others, and further passed by way of interconnections 9 in the interconnection layer 7 provided on the second surface side 1b of the device 100, so that a signal is taken outside.

The silicon epitaxial layer 2 (first semiconductor layer) of the semiconductor layer 1 is provided on a semiconductor substrate (silicon substrate for example) not illustrated. The silicon epitaxial layer 2 is a layer grown epitaxially on the silicon substrate, using a CVD (chemical vapor deposition) method for example.

The long wavelength absorption layer 3 (second semiconductor layer) is provided on the silicon epitaxial layer 2. The long wavelength absorption layer 3 is made of silicon germanium (SiGe) for example, and is provided to absorb light rays in the red-light-wavelength region (620 to 750 nm) effectively. The long wavelength absorption layer 3 made of silicon germanium (SiGe) is a layer grown epitaxially on the silicon epitaxial layer 2 by a CVD method for example.

When a silicon germanium is formed on a silicon, which is smaller in lattice constant than silicon germanium, a strain is generated in an interface between the silicon and the silicon germanium. When the strain exceeds a tolerance limit, bonds between atoms of the silicon germanium and atoms of the silicon are cleaved so that silicon atoms having dangling bonds are generated. The silicon atoms having the dangling bonds cause a crystal defect. When an image is reproduced from a signal charge generated in the solid state imaging device, the crystal defect causes the generation of a dark current or a white defect in the image to deteriorate the quality of the image.

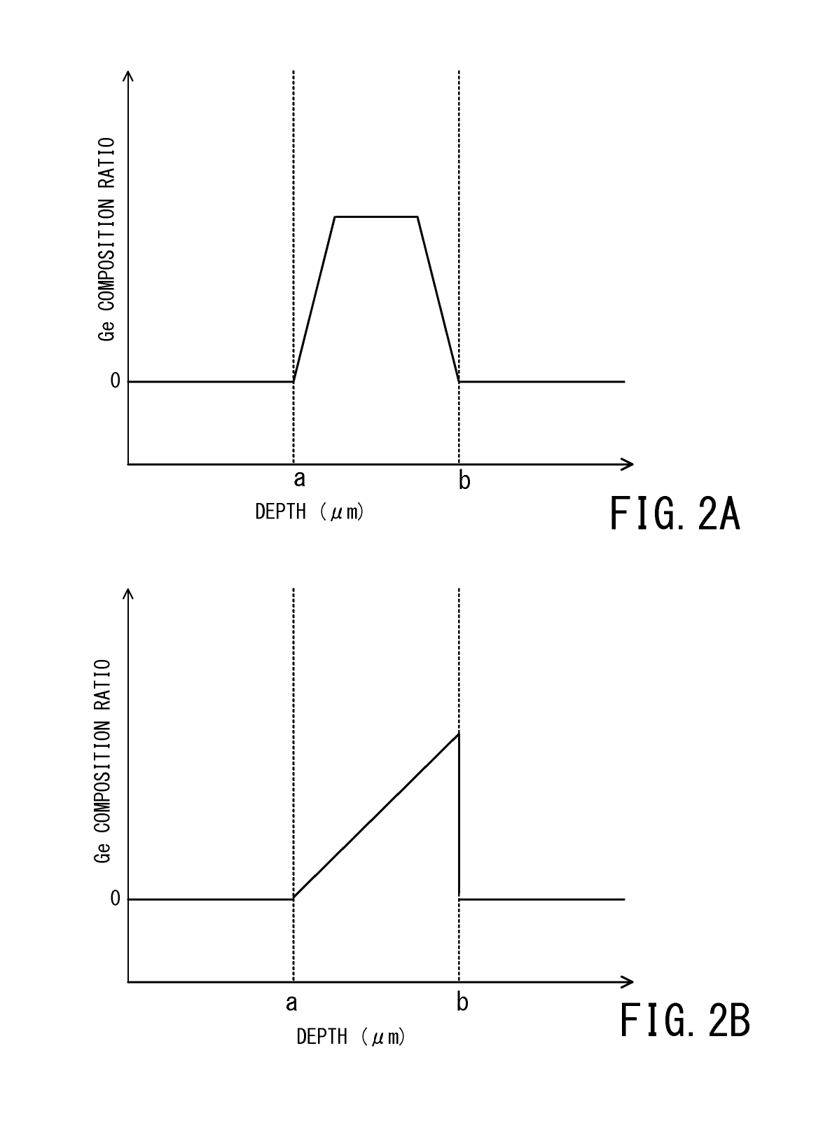

With reference to FIGS. 2A and 2B, a description is made about a method of restraining the generation of a crystal defect based on a lattice mismatch between silicon and silicon germanium. FIGS. 2A and 2B are each a graph showing Ge (germanium) composition ratio in SiGe (silicon germanium) of the long wavelength absorption layer 3 relative to the depth of the layer.

As illustrated in FIGS. 2A and 2B, in the long wavelength absorption layer 3, the composition ratio of germanium in silicon germanium is varied. In FIG. 2A for example, the Ge composition ratio is set in the manner not only of being gradually increased from zero from a point “a” (interface between the silicon epitaxial layer 2 and the long wavelength absorption layer 3) toward a point (b) (interface between the long wavelength absorption layer 3 and the silicon epitaxial layer 4) to reach a predetermined value, but also of being subsequently kept a constant value, and being then gradually decreased into zero. In FIG. 2B for example, the Ge composition ratio is set in the manner of being gradually increased from the point “a” toward the point “b”, and being then set to zero at the point “b”. The composition ratio referred to herein is the proportion of the amount of Ge atoms into the total amount of silicon atoms plus the germanium atoms, the Si and Ge atoms being atoms constituting the silicon germanium. The thickness of the silicon germanium film is set into the range of about 10 to 300 nm for example. It is allowable to form a buffer layer between the silicon epitaxial layer 2 and the long wavelength absorption layer 3 to relieve lattice mismatch between the silicon and the silicon germanium.

The silicon epitaxial layer 4 (third semiconductor layer) is a P-type semiconductor layer. The silicon epitaxial layer 4 is provided on the long wavelength absorption layer 3. The silicon epitaxial layer 4 is provided to restrain the generation of a leakage current. The silicon epitaxial layer 4 is a layer grown epitaxially on the long wavelength absorption layer 3 by a CVD method for example. It is allowable to form a buffer layer between the long wavelength absorption layer 3 and the silicon epitaxial layer 4 to relieve lattice mismatch between the silicon and the silicon germanium.

The N-type semiconductor regions 5 (first semiconductor regions) are located to extend over the respective insides of the silicon epitaxial layer 2, the long wavelength absorption layer 3 and the silicon epitaxial layer 4. Specifically, the N-type semiconductor regions 5 penetrate the long wavelength absorption layer 3 and the silicon epitaxial layer 4 in the state that the upper of the N-type semiconductor regions 5 is separated from the upper of the silicon epitaxial layer 2 and the bottom of the N-type semiconductor regions 5 is extended to the bottom of the silicon epitaxial layer 4.

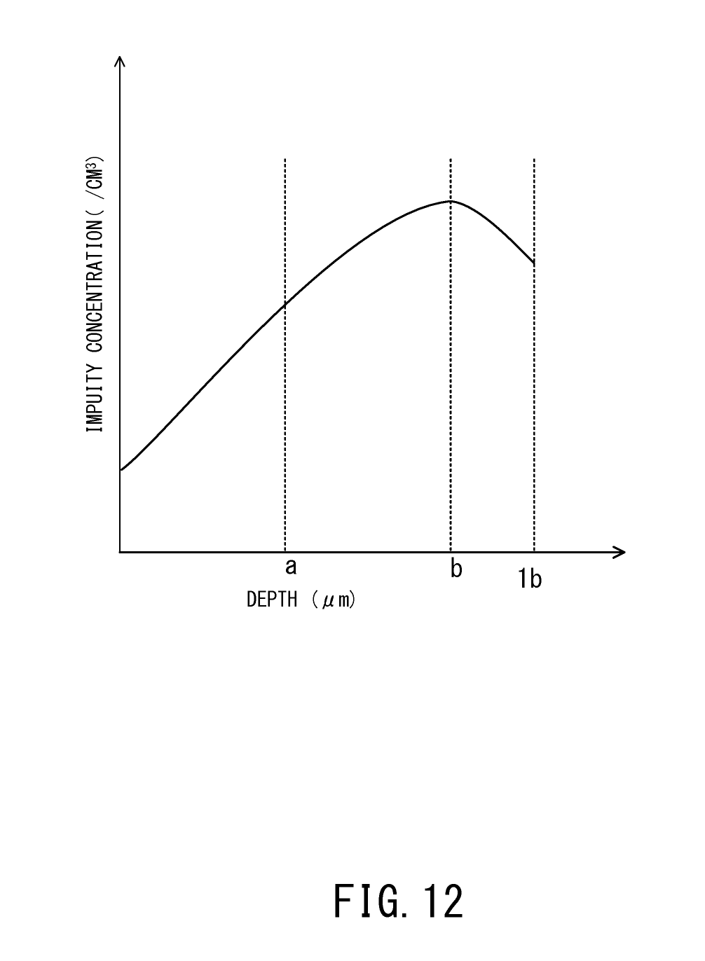

With reference to FIG. 12, a description is made about a profile of an impurity in each of the N-type semiconductor regions 5. FIG. 12 is a chart showing the profile of the impurity relative to the depth direction of the first semiconductor region. As shown in FIG. 12, the profile in the N-type semiconductor region 5 is set in the manner of being increased in impurity concentration from the upper of the region 5 toward the point “b” (interface between the long wavelength absorption layer 3 and the silicon epitaxial layer 4). The profile in the N-type semiconductor region 5 is set in the manner of having an impurity concentration peak near the point b (interface between the long wavelength absorption layer 3 and the silicon epitaxial layer 4). The profile in the N-type semiconductor region 5 is set in the manner of being decreased in impurity concentration from the point b toward the second surface 1b side of the region 5. The impurity in the N-type semiconductor regions 5 is phosphorous or arsenic for example. By locating the high-impurity-concentration regions, signal charges generated by photoelectric conversion are accumulated in sites high in impurity concentration.

In a method of forming the N-type semiconductor regions 5, a mask member not illustrated is used as a mask to implant ions of phosphorous (P) into the silicon epitaxial layer 2, the long wavelength absorption layer 3 and the silicon epitaxial layer 4 at an acceleration voltage of 650 to 4400 kV and a dose of 1×10¹² to 1×10¹³ cm⁻² for example. Instead of phosphorous (P), arsenic (As) may be used. In the case, it is preferred to change the acceleration voltage. In the ion implantation, it is preferred to vary the acceleration voltage among the silicon epitaxial layer 2, the long wavelength absorption layer 3 and the silicon epitaxial layer 4 in accordance with the respective impurity concentrations in these layers. After the ion implantation, the workpiece is subjected to annealing treatment (at a temperature of about 600 to 1150° C. for example) to activate the ion implanted layer. In this way, the N-type semiconductor regions 5 are formed. The thickness of the N-type semiconductor regions 5 is several hundreds of nanometers in the direction along which the layers are stacked in the semiconductor layer 1.

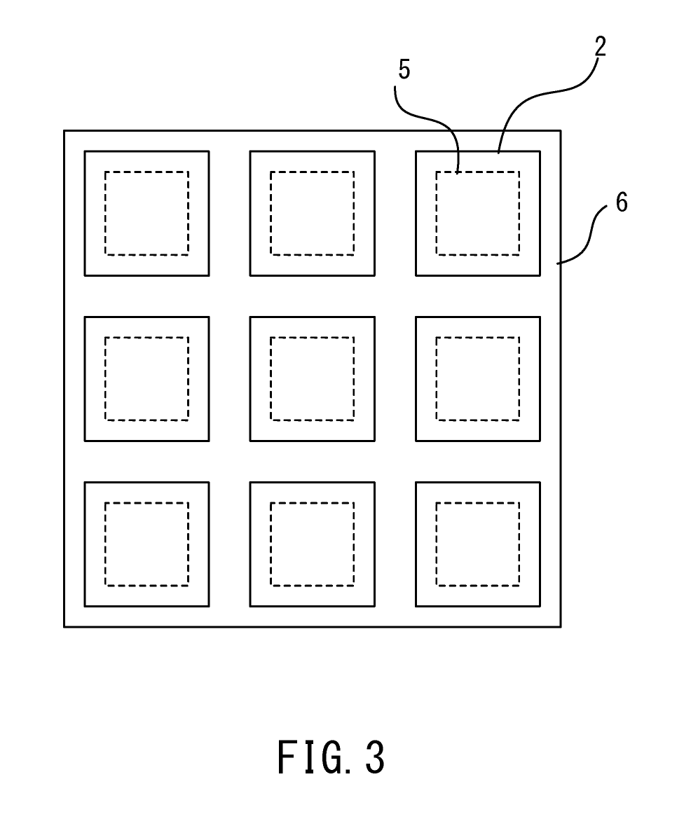

An element isolation portion 6 has a DTI (deep trench isolation) structure. The element isolation portion 6 is extended from the first surface 1a of the semiconductor layer 1 (the surface of the silicon epitaxial layer 2 that is opposite to the long wavelength absorption layer 3 side surface of the silicon epitaxial layer 2) into the silicon epitaxial layer 2. With reference to FIG. 3, a description is made about the element isolation portion 6 when the solid state imaging device is viewed along a direction perpendicular to the first surface 1a of the semiconductor layer 1. FIG. 3 is a plan view of the solid state imaging device along line A-A in FIG. 1. As illustrated in FIG. 3, the element isolation portion 6 is formed in a lattice form. Plural pieces of the silicon epitaxial layer 2, as well as the N-type semiconductor regions 5, are arranged. Each of the pieces of the silicon epitaxial layer 2 has a rectangular shape, and is surrounded by the element isolation portion 6. Each of the N-type semiconductor regions 5 has a rectangular shape. The N-type semiconductor region 5 is arranged inside the corresponding piece of the silicon epitaxial layer 2, and is surrounded by the element isolation portion 6.

When the solid state imaging device is viewed along a direction perpendicular to the upper side surface of the first surface 1a of the semiconductor layer 1, a pixel P is located inside a section formed by each lattice of the lattice-form element isolation portion 6. The pixel P is composed of the silicon epitaxial layer 2, the long wavelength absorption layer 3, the silicon epitaxial layer 4, and one of the N-type semiconductor regions 5.

The N-type semiconductor regions 5 are electrically separated from each other. Thus, it is possible to restrain a signal charge generated from any one of the pixels P by photoelectric conversion from invading, out of the entire pixels P, pixels P adjacent to the pixel P.

The element isolation portion 6 is formed by making a trench by an RIE (reactive ion etching) method, and burying the trench with an insulator film (such as a silicon oxide film, or a film of an oxide of a metal such as tungsten) by CVD method. About the element isolation portion 6, the depth and the width are from 300 to 600 nm, and from 40 to 200 nm, respectively, for example.

The color filters CF each transmit light rays in a wavelength region of one of red (R), green (G) and blue (B) of the three primary colors. One of the color filters CF having the respective wavelength regions of these colors is provided over (or, provided above) the silicon epitaxial layer 2 for each of the pixels P. When incident light is transmitted through the color filters CF, rays of the light in the respective wavelength regions of the three primary colors are selectively radiated into the respective three-species pixels P.

A microlens ML is arranged on the color filter CF for each of the pixels P. The microlens ML condenses incident light rays radiated into the pixel P (i.e., each of the pixels P).

The interconnection layer 7 is provided on the second surface 1b of the semiconductor layer 1. The interconnection layer 7 has an insulator film 8, the interconnections 9, and the pixel transistors 11. The pixel transistors 11 which each make a selection of one of the pixels P are arranged on the second surface 1b of the semiconductor layer 1. Specifically, a gate insulator film, a gate electrode, a source electrode and a drain electrode which constitute any one of the pixel transistors 11 are provided at a surface portion of the interconnection layer 7 contacting the silicon epitaxial layer 4. A source, a drain and a channel region which constitute the image forming device transistor 11 are provided on the surface of the silicon epitaxial layer 4 which contacts the interconnection layer 7. The pixel transistor 11 is covered with the insulator film 8. The interconnections 9 are formed to be in a multistage form and to interpose the insulator film 8 between the interconnections 9 and covered with the insulator film 8.

Each of the interconnections 9 functions as a transmission line, an address line, a vertical signal line, a reset line or some other line that is electrically connected to one of the pixel transistors 11.

A supporting substrate 10 is provided on the side of the interconnection layer 7 which is opposite to the silicon epitaxial layer 4 side of the interconnection layer 7. The supporting substrate 10 is a silicon substrate.

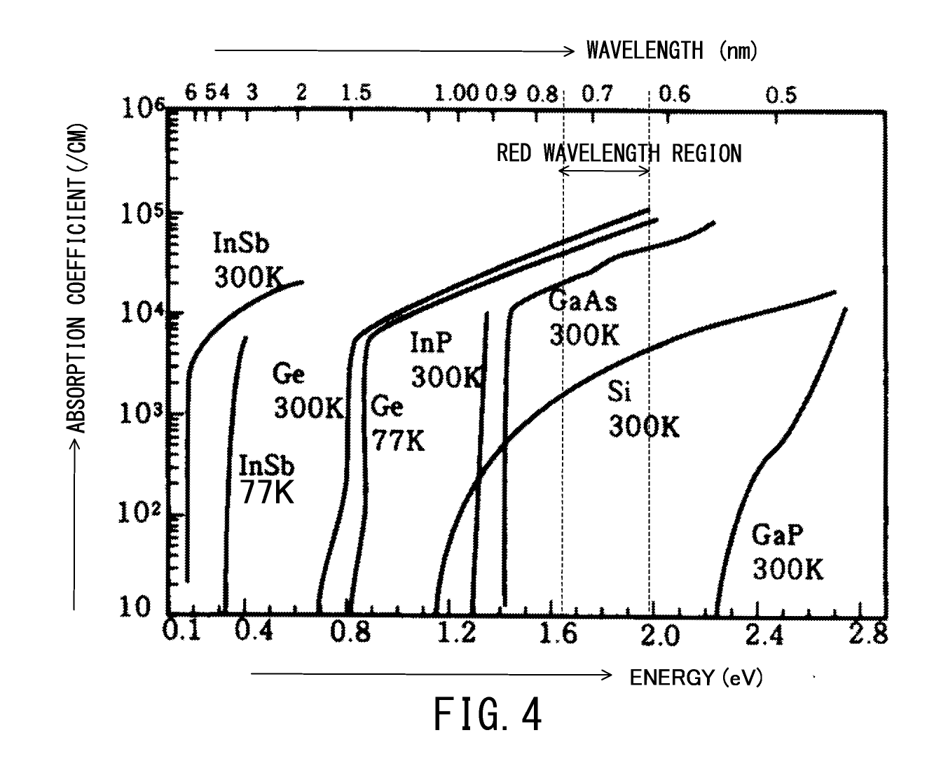

With reference to FIG. 4, the following will describe the action and advantageous effects of the solid state imaging device according to the embodiment. FIG. 4 is a characteristic diagram illustrating the absorption coefficient of each material relative to the wavelength (energy) of light.

In a non-illustrated solid state imaging device of a comparative example, a long wavelength absorption layer is made of silicon. In the solid state imaging device of the comparative example, light transmitted through each microlens ML of the device is radiated into the corresponding color filter CF. Out of rays of the light transmitted through the color filter CF, light rays in a predetermined wavelength region are selectively into an N-type semiconductor region 5 of the device. When the color filter CF is a blue (B) color filter or a green (G) color filter for example, the color filter CF causes light rays in the blue (B) wavelength region or the green (G) wavelength region, out of the radiated-into light rays, to be selectively radiated into the N-type semiconductor region 5. The light rays absorbed in the N-type semiconductor region 5 generate signal charges. The signal charges are accumulated in a high-impurity-concentration portion of the N-type semiconductor region 5. When the color filter CF is a red (R) color filter, the color filter CF causes light rays in the red (R) wavelength region, out of the radiated-into light rays, to be selectively radiated into the N-type semiconductor region 5.

As illustrated in FIG. 4, the silicon type solid state imaging device of the comparative example cannot sufficiently absorb any light ray in the red (R) wavelength region (wavelength of 620 to 750 nm, and energy of 1.65 to 1.99 eV). Specifically, at room temperature (300 K), silicon (Si) absorbs light in only a quantity of about 1/30 of the absorbed quantity of germanium (Ge), and in only a quantity of about 1/10 of the absorbed quantity of GaAs. For this reason, out of light rays in the red (R) wavelength region, light rays not absorbed into a silicon epitaxial layer 2 of the comparative example are absorbed into the silicon long wavelength absorption layer so that signal charges are generated. The signal charges are accumulated in respective high-impurity-concentration portions of the N-type semiconductor regions 5. Thereafter, the signals are transmitted to the respective pixel transistors 11, so that the signal charges accumulated in the N-type semiconductor regions 5 are read out, transmitted and then outputted successively into an external output circuit.

In the solid state imaging device 100 of the embodiment, the long wavelength absorption layer 3 is arranged. The long wavelength absorption layer 3 is a layer making use of silicon germanium (SiGe) composed of germanium (Ge), which shows light rays in the red (R) wavelength region a high absorption coefficient, and silicon (Si). For this reason, the solid state imaging device 100 of the embodiment can sufficiently absorb light rays in the red (R) wavelength region. Since the long wavelength absorption layer 3 made of silicon germanium (SiGe) can sufficiently absorb light rays in the red (R) wavelength region, the silicon epitaxial layer 2 can be made thin. Since the element isolation portion 6 can be thinly formed, the generation of a crystal defect resulting from the element isolation portion 6 can be restrained. The generation of a dark current can be restrained, so that the quality of the resultant images can be improved.

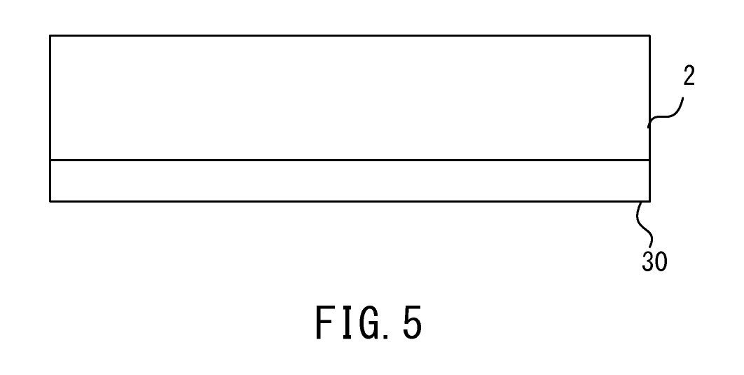

With reference to FIGS. 5 to 10, a description will be described about a method of fabricating the solid state imaging device 100 of the embodiment. FIGS. 5 to 10 are each a sectional view of a step in the process of fabricating the solid state imaging device.

As illustrated in FIG. 5, monosilane (SiH₄) gas and diborane (B₂H₆) for example are used as a silicon gas source and a P-type doping gas, respectively, to cause an epitaxial growth onto a semiconductor substrate 30. As a result, a silicon epitaxial layer 2 is formed on the semiconductor substrate 30. In this process, P-type silicon is used for the semiconductor substrate 30.

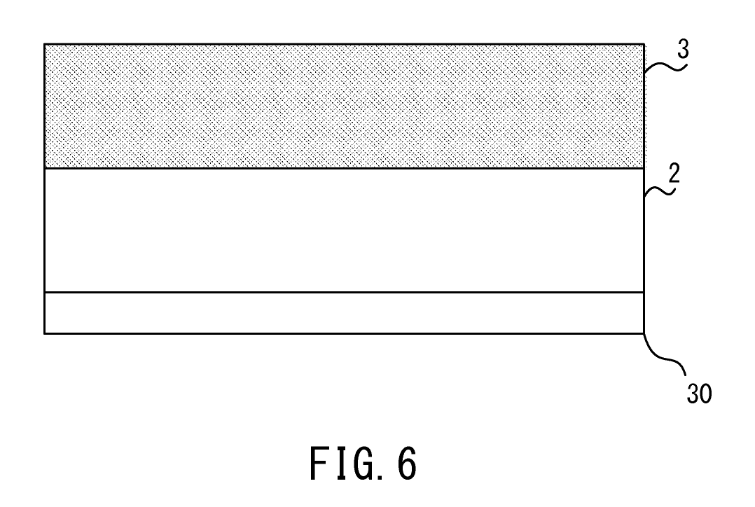

As illustrated in FIG. 6, monosilane gas, diborane (B₂H₆) gas and mono germane (GeH₄) gas are used as a silicon source gas, a P-type doping gas and a germanium source gas, respectively, to cause an epitaxial growth onto the silicon epitaxial layer 2. As a result, a long wavelength absorption layer 3 made of silicon germanium is formed. At the time of the start of the growth of the silicon germanium layer, the supply flow rate of germane gas is set to zero. As the growth time elapses, the supply flow rate of germane gas is increased. When the supply flow rate of germane gas has reached to a predetermined value, the supply flow rate is then maintained for a predetermined period. Thereafter, the supply flow rate of germane is gradually decreased down to zero, so that the growth of silicon germanium is ended. By causing silicon germanium to grow in this way, the Ge composition ratio in the long wavelength absorption layer 3 gives a profile as has been shown in FIG. 2A. The Ge composition ratio is zero in the interface (“a” in FIG. 2A) between the silicon epitaxial layer 2 and the long wavelength absorption layer 3, and increases gradually toward the silicon epitaxial layer 4. Thereafter, the Ge composition ratio is kept a constant value, and then decreases gradually toward the silicon epitaxial layer 4. The ratio turns to zero in the interface (“b” in FIG. 2A) between the long wavelength absorption layer 3 and the silicon epitaxial layer 4.

The Ge composition ratio may be adjusted into another profile. Specifically, at the time of the start of the growth of silicon germanium, the supply flow rate of germane gas is set to zero. As the growth time elapses, the supply flow rate of germane gas is gradually increased. When a predetermined growth period has elapsed, the growth of silicon germanium is ended. As has been shown in FIG. 2B, the Ge composition ratio in the long wavelength absorption layer 3 is zero in the interface (“a” in FIG. 2B) between the silicon epitaxial layer 2 and the long wavelength absorption layer 3, and increases gradually toward the silicon epitaxial layer 4. As a result, in the long wavelength absorption layer 3, the Ge composition ratio becomes higher from the silicon epitaxial layer 2 toward the silicon epitaxial layer 4. Strains caused by lattice mismatch between silicon and silicon germanium come to be gradually generated in the long wavelength absorption layer 3. It is therefore possible to decrease crystal defects in the interface between the silicon epitaxial layer 2 and the long wavelength absorption layer 3.

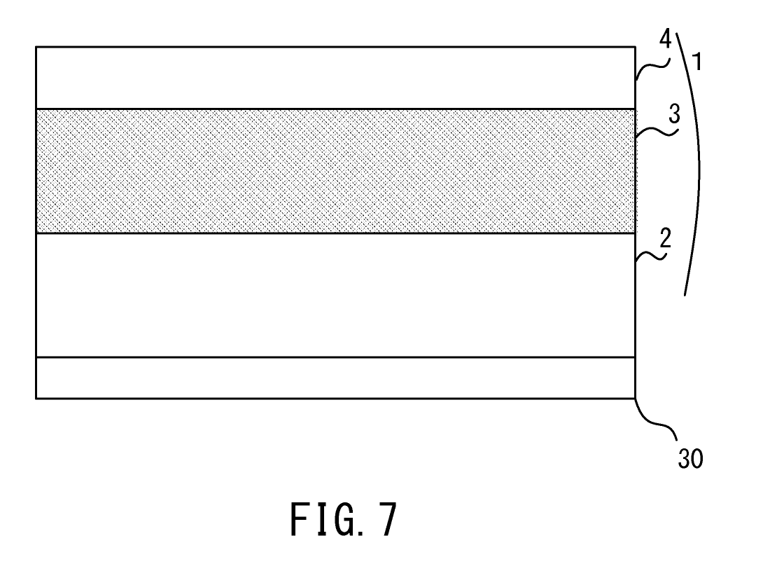

As illustrated in FIG. 7, monosilane gas and diborane gas are used to cause an epitaxial growth onto the long wavelength absorption layer 3. As a result, a silicon epitaxial layer 4 is formed on the long wavelength absorption layer 3. Thus, a semiconductor layer 1 is formed which is composed of the silicon epitaxial layer 2, the long wavelength absorption layer 3, and the silicon epitaxial layer 4.

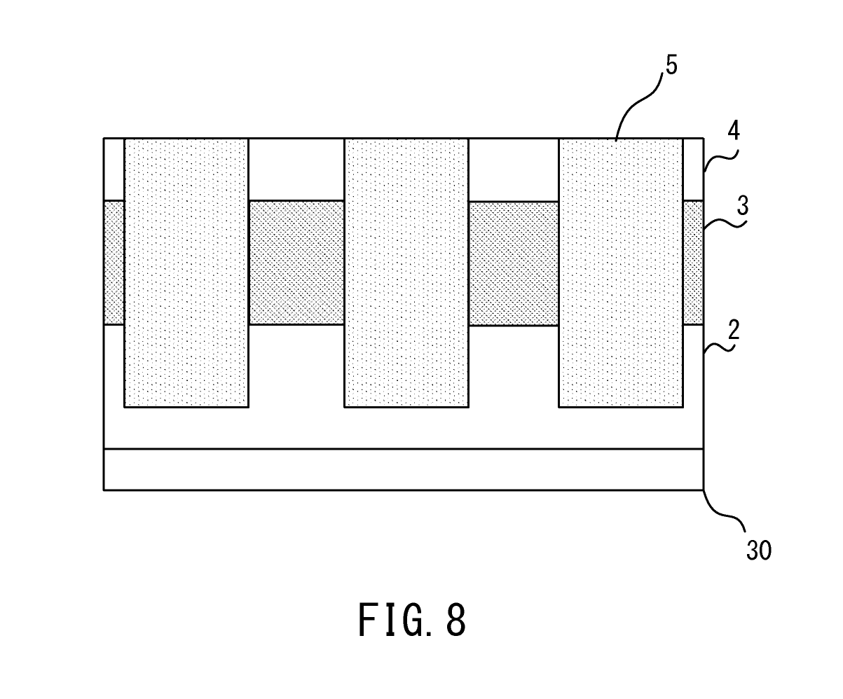

As illustrated in FIG. 8, a resist pattern not illustrated is formed on the silicon epitaxial layer 4. The film thickness of the resist is set into the range of 5 to 15 mm for example. The resist pattern is used as a mask to implant ions of an N-type impurity (such as phosphorous or arsenic) into the silicon epitaxial layer 4. About conditions for the ion implantation, the acceleration voltage and the dose are set into the range of 650 to 4400 kV and that of 1×10¹² to 1×10¹³ cm⁻² for example. After the ion implantation, the workpiece is subjected to annealing treatment at about 600 to 1150° C. for example to diffuse the impurity thermally and activate the impurity.

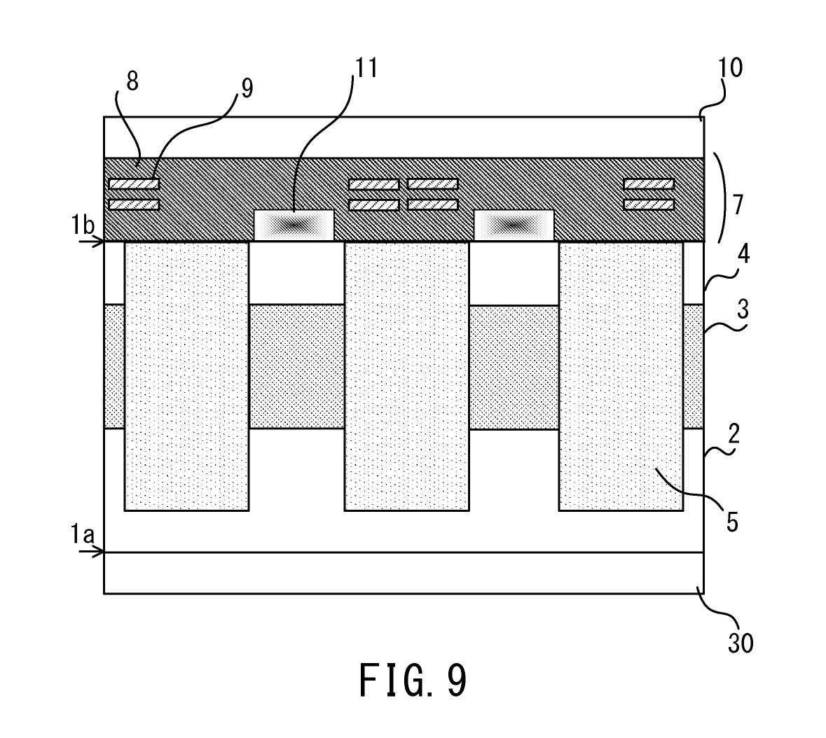

As illustrated in FIG. 9, pixel transistors 11 are formed on the second surface 1b of the semiconductor layer 1. After the formation of the pixel transistors 11, an insulator film 8 and interconnections 9 are formed. In this way, an interconnection layer 7 is formed which is composed of the insulator film 8, the interconnections 9 and the pixel transistors 11.

After the formation of the interconnection layer 7, a supporting substrate 10 is bonded onto the upper surface of the interconnection layer 7.

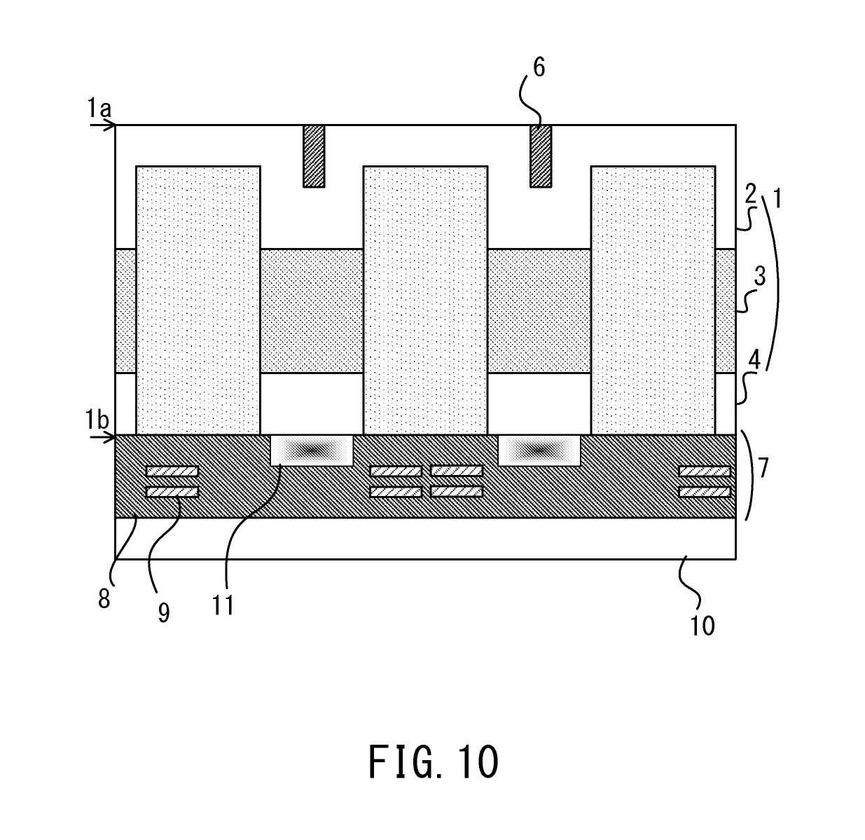

As illustrated in FIG. 10, a CMP (chemical mechanical polish) method for example is used to remove the semiconductor substrate 30. After the removal of the semiconductor substrate 30, a resist pattern not illustrated is formed on the silicon epitaxial layer 2. The resist pattern has openings in portions of the pattern which correspond to a planar shape of an element isolation portion 6 (to be formed). From the openings, the outer surface of the silicon epitaxial layer 2 is naked. The openings in the resist pattern correspond to a region which is to be the element isolation portion 6. As has been illustrated in FIG. 3, the openings in the resist pattern are each in a lattice form. The resist pattern is used as a mask to etch the silicon epitaxial layer 2 into a predetermined depth, using an RIE method for example. As a result, a trench is made from the upper surface of the silicon epitaxial layer 2 toward the silicon epitaxial layer 4. The depth of the trench is from several nanometers to several millimeters.

The resist pattern is used as a mask to implant ions of a P-type impurity for example into the side surfaces and the bottom surface of the trench, using an angled ion implantation technique. The P-type impurity ions used therein are ions of boron. The angled ion implantation technique is the implantation of ions into the side walls of the trench at an angle at which the implantation is attained to be slightly inclined to the side walls. After the angled ion implantation, the workpiece is subjected to annealing treatment to activate the ion implanted layer.

An insulator film is deposited into the trench and on the outer surface of the silicon epitaxial layer 2. The insulator film used in the case is a silicon oxide (SiO₂) film for example. Instead of the insulator film, a metal oxide film may be used. The usable metal oxide film is a tungsten oxide film for example. The silicon oxide film or the metal oxide film is formed, using a CVD method for example.

A CMP method for example is used to flatten and polish the insulator film formed over the first surface 1a of the semiconductor layer 1. As a result, the element isolation portion 6, in which the insulator film is buried in the trench, extends from the outer surface of the silicon epitaxial layer 2 into the silicon epitaxial layer 2.

Color filters CF are formed onto the silicon epitaxial layer 2. The color filters CF are each formed by painting a coating solution containing a color pigment and a photoresist resin onto the first surface 1a of the semiconductor layer 1, using a spin coating method for example. After the painting, a lithographic technique for example is used to perform patterning-work in the unit of some of the pixels P. A microlens ML is formed onto the color filter CF for each of the pixels P.

Through the above-mentioned fabricating process, the solid state imaging device 100 (see FIG. 1) is finished.

As described above, the solid state imaging device 100 of the embodiment has the semiconductor layer 1, the N-type semiconductor regions 5, the interconnection layer 7, the color filters CF, and microlenses ML. The semiconductor layer 1 has the silicon epitaxial layer 2 (first semiconductor layer), the long wavelength absorption layer 3 (second semiconductor layer), and the silicon epitaxial layer 4 (third semiconductor layer). The long wavelength absorption layer 3 is made of silicon germanium (SiGe). In the long wavelength absorption layer 3, the Ge composition ratio is set in the manner of being gradually increased from zero to reach up to a predetermined value from the interface between the silicon epitaxial layer 2 and the long wavelength absorption layer 3 toward the interface between the long wavelength absorption layer 3 and the silicon epitaxial layer 4, and being subsequently kept the predetermined value constantly, and then gradually decreased to zero.

For this reason, in the interface between the silicon epitaxial layer 2 and the long wavelength absorption layer 3, it is possible to restrain the generation of crystal defects caused by lattice mismatch between silicon germanium and silicon. The restraint of the generation of the crystal defects makes it possible to restrain the generation of a dark current or white defect in the solid state imaging device 100. Accordingly, the resultant images can be improved in quality.

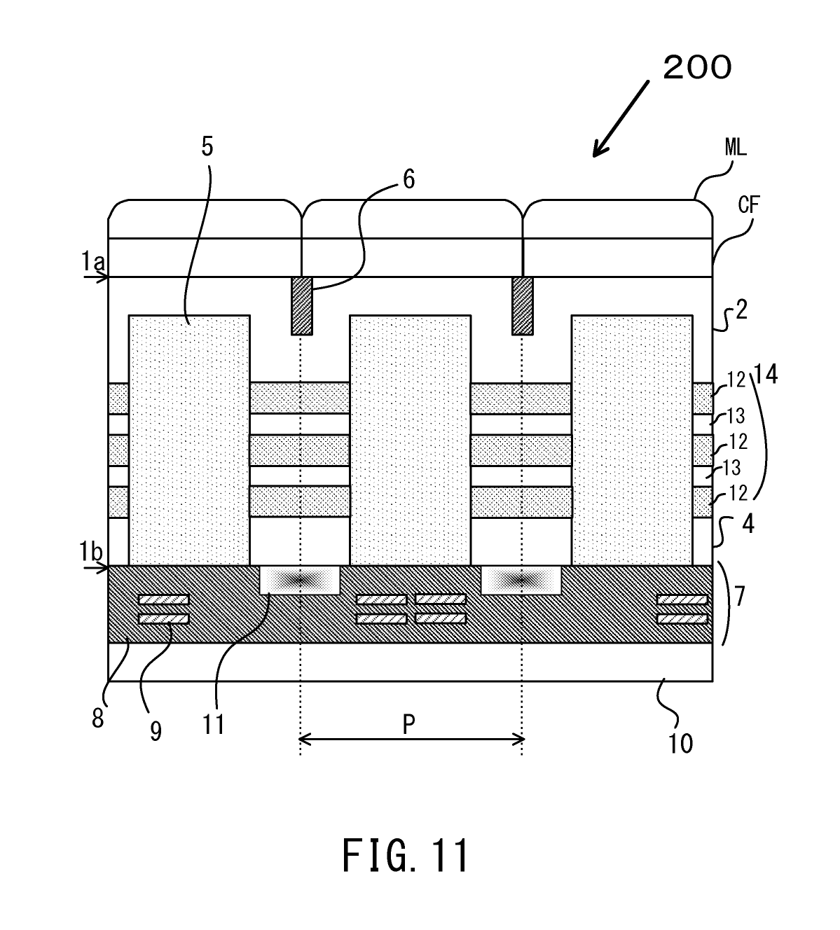

With reference to FIG. 11, a solid state imaging device according to a second embodiment of the invention will be described. FIG. 11 is a sectional view of a configuration of the solid state imaging device.

As illustrated in FIG. 11, the solid state imaging device, which is a device 200, makes use of a superlattice layer instead of the long wavelength absorption layer. The supperlattice layer, which is a layer 14, is a P-type semiconductor layer. Specifically, in the supperlattice layer 14, a first light absorption layer 12 made of silicon germanium and a second light absorption layer 13 made of silicon are repeatedly formed so that plural first absorption layers 12 (fifth semiconductor layers) are formed alternately with plural second light absorption layers 13 (sixth semiconductor layers). Members and portions other than the superlattice layer 14 are equal to those in the solid state imaging device 100 of the first embodiment. Thus, description about the members and portions is omitted.

The top most layer of the first light absorption layers 12 (fifth semiconductor layers), which partially constitute the superlattice layer 14, contacts a silicon epitaxial layer 2 (first semiconductor layer). A bottommost layer of the second light absorption layers 13 (fifth semiconductor layers), which partially constitute the super lattice layer 14, contacts a silicon epitaxial layer 4 (third semiconductor layer). The first light absorption layers 12 and the second light absorption layers 13 are formed by a CVD method for example.

The superlattice layer 14 is formed by a method of supplying germane when one of the first light absorption layers 12 is formed, stopping the supply of germane when one of the second light absorption layers 13 is formed, and repeating the supply and the stop alternately, for example. By changing the supply flow rate of germane periodically, the superlattice layer 14 may be formed.

It is preferred to make the first light absorption layers 12 lower in germanium composition ratio than the long wavelength absorption layer 3 according to the first embodiment, which is made of silicon germanium. It is preferred to set the germanium composition ratio in each of the first light absorption layers 12 and the thickness of the layers 12 not to generate a crystal defect based on lattice relaxation when each of the first light absorption layers 12 grows over the silicon epitaxial layer 2. The super lattice structure 14 is set to cause the germanium composition ratio averaged in the whole of the structure to have a predetermined value. According to the setting, in the super lattice structure 14, the generation of a crystal defect is restrained which is based on lattice mismatch between silicon germanium and silicon.

As described above, the solid state imaging device 200 of the embodiment has the silicon epitaxial layer 2, the supperlattice layer 14, the silicon epitaxial layer 4, and the same N-type semiconductor regions 5, interconnection layer 7, color filters CF, and microlenses ML. In the supperlattice layer 14, one of the first light absorption layers 12, which are made of silicon germanium, and one of the second light absorption layers 13, which are made of silicon, are repeatedly formed, so that the first light absorption layers 12 are formed alternately with the second light absorption layers 13.

For this reason, the second embodiment produces the same advantageous effects as the solid state imaging device 100 of the first embodiment.

While certain embodiments have been described, these embodiments have been presented by way of example only, and are not intended to limit the scope of the inventions. Indeed, the embodiments described herein may be embodied in a variety of the other forms; furthermore, various omissions, substitutions and changes in the form of the embodiments described herein may be without departing from the spirit of the inventions. The accompanying claims and their equivalents are intended to cover such forms or modifications as would fall within the scope and spirit of the inventions.

What is claimed is:

1. A solid state imaging device, comprising:
a first semiconductor layer of a first conductivity type;
a second semiconductor layer of the first conductivity type, the second semiconductor layer being provided on the first semiconductor layer and being larger in absorbance coefficient to light rays in a long wavelength region than the first semiconductor layer;
a third semiconductor layer of the first conductivity type, the third semiconductor layer being provided on the second semiconductor layer;
first semiconductor regions of a second conductivity type, the regions being located to extend over the respective insides of the first, second and third semiconductor layers, and arranged apart from each other in a first direction parallel to the upper surface of the first semiconductor layer; and
an element isolation portion arranged between adjacent ones of the first semiconductor regions.

2. The device according to claim 1, further comprising an interconnection layer,
the interconnection layer is provided over the third semiconductor layer, the interconnection layer including a pixel transistor which is provided on the third semiconductor layer, an insulator film which is provided over the third semiconductor layer to cover the pixel transistor, and an interconnection which is provided in the insulator film and connected electrically to the pixel transistor.

3. The device according to claim 1, wherein
the second semiconductor layer is composed of silicon germanium, and
the first and third semiconductor layers are composed of silicon.

4. The device according to claim 3, wherein
the composition ratio of germanium in the silicon germanium increases from the first semiconductor layer toward the third semiconductor layer.

5. The device according to claim 1, wherein
the second semiconductor layer has a structure in which fifth semiconductor layers having silicon germanium of the first conductivity type, and sixth semiconductor layers having silicon of the first conductivity type are alternately stacked onto each other.

6. The device according to claim 1, wherein
the first semiconductor layer is higher in impurity concentration than the third semiconductor layer.

7. The device according to claim 1, wherein
the first semiconductor regions have an impurity concentration increasing from the first semiconductor layer toward the third semiconductor layer, and the impurity concentration has a peak near an interface between the second and third semiconductor layers.

8. The device according to claim 1, wherein
the element isolation portion is any one of silicon oxide films and metal oxide films.

9. The device according to claim 1, wherein
the upper surface of the element isolation portion has the same height as the upper surface of the first semiconductor layer, and the bottom surface of the element isolation portion extends more deeply than the upper surface of the first semiconductor regions but does not reach the second semiconductor layer.

10. The device according to claim 1, further comprising:
a color filter arranged for each pixel, and provided over the first semiconductor layer to be oppositely to the second semiconductor layer.

11. The device according to claim 10, further comprising:
a microlens arranged for the pixel, and provided over the color filter.

12. The device according to claim 1, further comprising:
a supporting substrate is provided over the interconnection layer.

13. The device according to claim 12, wherein
the supporting substrate is a silicon substrate.

14. The device according to claim 1, wherein
the first semiconductor regions is a photoelectric conversion element.

15. A method of fabricating a solid state imaging device, comprising:
forming a first semiconductor layer of a first conductivity type on a semiconductor substrate by epitaxial growth of silicon;
forming a second semiconductor layer of the first conductivity type on the first semiconductor layer by epitaxial growth of silicon germanium;
forming a third semiconductor layer of the first conductivity type on the second semiconductor layer by epitaxial growth of silicon;
forming a first semiconductor regions of a second conductivity type, the regions being arranged apart from each other inside the first, second and third semiconductor layers;
removing the semiconductor substrate;
forming an element isolation portion extending from the upper surface of the first semiconductor layer, from which the semiconductor substrate has been removed, into the first semiconductor layer, the unit being arranged between adjacent ones of the first semiconductor regions in a first direction parallel to the upper surface of the first semiconductor layer; and
forming a color filter over the first semiconductor layer.

16. The method according to claim 15, wherein
in the step of forming the second semiconductor layer, control is made about the supply amount of a raw material for germanium to increase the composition ratio of germanium in silicon germanium along a third direction perpendicular to the upper surface of the first semiconductor layer from the first semiconductor layer, thereby growing the silicon germanium epitaxially.

17. The method according to claim 15, wherein
in the step of forming the second semiconductor layer is a step of repeating the following sub-steps alternately: a sub-step of forming a fifth semiconductor layer having silicon germanium of the first conductivity type; and a sub-step of forming a sixth semiconductor layer having silicon of the first conductivity type.

18. The method according to claim 15, wherein
in the step of forming the second semiconductor layer, the supply amount of the germanium raw material is periodically changed.
